(19) United States
(12) Patent Application Publication
(10) Pub. No.: US 2013/0277186 A1
(43) Pub. Date: Oct. 24, 2013

(54) TOUCH PANEL

(71) Applicant: FUJITSU COMPONENT LIMITED, Tokyo (JP)

(72) Inventors: Mitsuhiro Sekizawa, Tokyo (JP); Shigemi Kurashima, Toyo (JP)

(73) Assignee: FUJITSU COMPONENT LIMITED, Tokyo (JP)

(21) Appl. No.: 13/866,143

(22) Filed: Apr. 19, 2013

(30) Foreign Application Priority Data
Apr. 23, 2012 (JP) 2012-098232

(51) Int. Cl. H03K 17/96

(52) U.S. Cl. CPC H03K 17/9618
USPC 200/181

(57) ABSTRACT

A touch panel includes a first conductive film including conductive patterns each extending in one direction, and a second conductive film facing the first conductive film. Each of the conductive patterns includes plural diamond-shaped parts aligned in the one direction, and a connection part connecting adjacent diamond-shaped parts each other, and each conductive pattern has a uniform resistance value per unit length.

### CROSS-REFERENCE TO RELATED APPLICATIONS

This application is based upon and claims the benefit of priority of the prior Japanese Patent Application No. 2012-098232 filed on Apr. 23, 2012, the entire contents of which are hereby incorporated by reference.

### BACKGROUND

1. Field of the Invention

The present invention generally relates to a touch panel.

2. Description of the Related Art

A touch panel is an input device that allows direct input to be performed on a display. The touch panel, which is often positioned at the front of a display, allows direct input based on data that can be visually recognized through the display. Therefore, touch panels are used for various purposes.

Among the touch panels, the electrostatic capacity type touch panel and the resistant film type touch panel are widely known. The resistant film type touch panel includes upper and lower electrode substrates each having a transparent conductive film formed thereon. The upper and lower electrode substrates are positioned in a manner such that their transparent conductive films face each other. By applying pressure to a single point on the upper electrode surface, the transparent conductive films are forced to contact each other. By detecting the point of the contact, the position of the point with pressure applied can be detected.

The resistant film type touch panel can be broadly categorized into a four-wire type, a five-wire type, and a diode type. The four-wire type touch panel has an x-axis electrode provided in one of the upper and lower electrode substrates and a y-axis electrode provided in the other of the upper and lower electrode substrates (see, for example, Japanese Laid-Open Patent Publication No. 2004-272722). The five-wire type touch panel has both x and y axis electrodes provided on a lower electrode substrate, and an upper electrode substrate functioning as a probe for detecting voltage (see, for example, Japanese Laid-Open Patent Publication No. 2008-293129). The diode type touch panel has a structure including a diode(s) provided to a lower electrode substrate. The diode type touch panel is also referred to as a seven-wire type touch panel because the diode type touch panel has two electrodes for applying voltage, four electrodes for monitoring electric potential, and an electrode provided to an upper electrode substrate serving as a probe for detecting voltage (see, for example, Japanese Laid-Open Patent Publication No. 2005-196280).

With the electrostatic capacity type touch panel, an electric current flowing in, for example, a transparent electrode of the touch panel is detected by positioning a finger or the like close to the touch panel. By detecting the current, position can be detected. In view of the different characteristics of the electrostatic capacity type touch panel and the resistant film type touch panel, there is a touch panel having a layered structure that includes the electrostatic capacity type touch panel and the resistant film type touch panel (see, for example, Japanese Registered Utility Model Nos. 3132106 and 3139196).

Because the electrostatic capacity type touch panel uses a detection method using capacitive coupling, the electrostatic capacity type touch panel has a characteristic of being able to detect position by simply being touched without being depressed. However, the electrostatic capacity type touch panel is unable to detect position by being touched by an insulator. Further, although the resistant film type touch panel is capable of detection regardless of the material or the like used for contacting the touch panel, a predetermined amount of force is required to be applied to the touch panel because the resistant film type touch panel detects position by the contact between a transparent conductive film serving as an upper resistance film and a transparent conductive film serving as a lower resistance film.

On the other hand, the touch panel disclosed in Japanese Registered Utility Model Nos. 3132106 and 3139196, which has a layered structure including the electrostatic capacity type touch panel and the resistant film type touch panel, has the favorable characteristics of both the electrostatic capacity type touch panel and the resistant film type touch panel. However, the touch panel having the layered structure has problems of becoming too thick and high cost because the touch panel has two types of touch panels layered one on top of the other.

### SUMMARY

An embodiment of the present invention provides a touch panel including a first conductive film including conductive patterns each extending in one direction, and a second conductive film facing the first conductive film, wherein each of the conductive patterns includes plural diamond-shaped parts aligned in the one direction, and a connection part connecting adjacent diamond-shaped parts each other, and each conductive pattern has a uniform resistance value per unit length.

Other objects and further features of the present invention will be apparent from the following detailed description when read in conjunction with the accompanying drawings.

### BRIEF DESCRIPTION OF THE DRAWINGS

FIG. 1 is schematic diagram of a touch panel according to an embodiment of the present invention;

FIG. 2 is a schematic diagram for describing a first transparent conductive film of a touch panel;

FIGS. 3A and 3B are schematic diagrams for describing potential distribution of a transparent conductive film;

FIGS. 4A and 4B are schematic diagrams for describing potential distribution of a transparent conductive film;

FIG. 5 is a schematic diagram for describing a touch panel according to an embodiment of the present invention;

FIG. 6 is an enlarged view of a portion of the touch panel illustrated in FIG. 5;

FIG. 7 is a schematic diagram for describing a touch panel according to another embodiment of the present invention;

FIG. 8 is an enlarged view of a portion of the touch panel illustrated in FIG. 7;

FIG. 9 is a schematic diagram for describing a touch panel according to another embodiment of the present invention;

FIG. 10 is a schematic diagram for describing an alternative example of the touch panel illustrated in FIG. 9;

FIG. 11 is a schematic diagram for describing another alternative example of the touch panel illustrated in FIG. 9;

FIG. 12 is a cross-sectional view of a first substrate taken along a dash-dot line 11A-11B of FIG. 11;

FIG. 13 is a schematic diagram for describing a resistance value of wirings;

FIG. 14 is a schematic diagram for describing another alternative example of the touch panel illustrated in FIG. 9;

FIG. 15 is a schematic diagram for describing a proportion of a resistance value of wirings;

FIGS. 16A and 16B are schematic diagrams for describing a contact part between a first transparent conductive film and a wiring; and

FIGS. 17A and 17B are schematic diagrams for describing a contact part between a first transparent film and a wiring according to an embodiment of the present invention.

### DESCRIPTION OF EMBODIMENTS

In the following, embodiments of a touch panel of the present invention are described with reference to the accompanying drawings. It is to be noted that like components are denoted with like reference numerals throughout the following description and drawings.

### First Embodiment

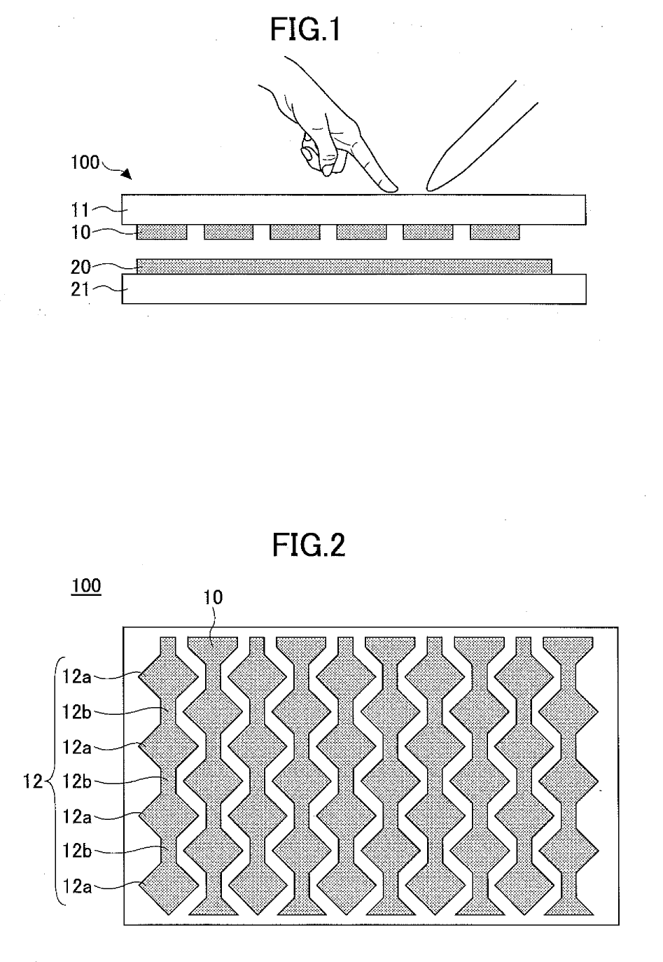

FIG. 1 illustrates a touch panel 100 according to a first embodiment of the present invention. As illustrated in FIG. 1, the touch panel 100 of the first embodiment includes a first substrate 11, a first transparent conductive film 10 formed on one surface of the first substrate 11, a second substrate 21, and a second transparent conductive film 20 formed on one surface of the second substrate 21. The first and second substrates 11, 21 are arranged in a state having the first and second transparent conductive films 10, 20 facing each other. The touch panel 100 of the first embodiment can perform electrostatic capacity type position detection by using the first transparent conductive film 10 and perform resistant film type position detection by using the first and second transparent conductive films 10, 20.

In the touch panel 100 capable of performing both the electrostatic capacity type position detection and the resistant film type position detection, the first transparent conductive film 10 includes one or more diamond patterns 12 as illustrated in FIG. 2. The diamond pattern 12 is formed as a single row of conductive material including parts having a diamond shape (hereinafter referred to as “diamond-shaped parts”) 12a and parts connecting adjacent diamond-shaped parts (hereinafter referred to as “connection parts”) 12b. By forming the first transparent conductive film 10 with the diamond patterns 12, the touch panel 100 can perform electrostatic capacity type position detection.

In order to perform resistant film type position detection with high accuracy by using the first and second transparent conductive films 10, 20, the space between the diamond patterns 12 is be as narrow as possible.

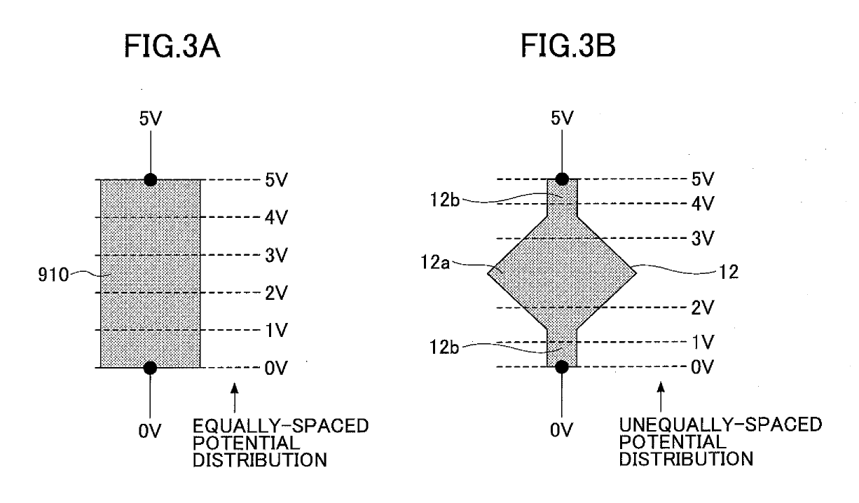

In a case of using the first transparent conductive film 10 including the diamond pattern 12 for resistant film type position detection, the voltage of the first transparent conductive film 10 and the position of the first transparent conductive film 10 do not exhibit a linear relationship. As illustrated in FIG. 3A, in a case where a first transparent conductive film includes a pattern 910 with constant width, the pattern 910 generates a potential distribution of equal space when a voltage of 5V is applied to one end of the pattern 910 and a voltage of 1V is applied to the other end of the pattern 910. If such equally spaced potential distribution can be generated, a linear relationship can be established between a potential of a transparent conductive film and a contact position of the transparent conductive film. Therefore, accurate position detection can be performed by referring to a potential detected from a contact position of the transparent conductive film.

On the other hand, as illustrated in FIG. 3B, in a case where the first transparent conductive film 10 includes the diamond pattern 12 constituted by the diamond-shaped parts 12a and the diamond connection parts 12b, the diamond pattern 12 does not generate a potential distribution of equal space when a voltage of 5V is applied to the diamond connection part 12b on one end of the diamond-shaped part 12a and a voltage of 0V is applied to the diamond connection part 12b on the other end of the diamond-shaped part 12a. Because the potential of the first transparent conductive film 10 and the contact position of the first transparent conductive film 10 do not establish a linear relationship, it is difficult to perform position detection by referring to an electrical potential detected from a contact position of the transparent conductive film 10. Therefore, in a case where the diamond pattern 12 is formed in the first transparent conductive film 10, it is difficult to perform accurate position detection by referring to a potential detected from a contact position of the transparent conductive film 10.

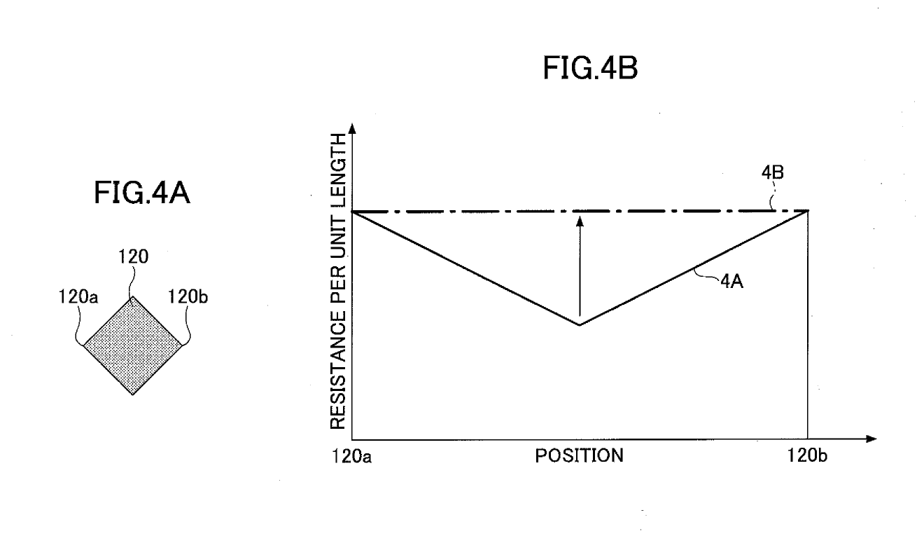

The difficulty of performing accurate position detection with the first transparent conductive film 10 including the diamond pattern 12 is described in detail with reference to a diamond-shaped pattern 120 (corresponding to diamond-shaped part 12a) as illustrated in FIG. 4A. In a case of the diamond-shaped pattern 120 illustrated in FIG. 4A, the resistance value per a unit length from one corner 120a of the diamond-shaped pattern 120 to the opposite corner 120b is as illustrated with a solid line 4A in FIG. 4B.

As illustrated with the solid line 4A of FIG. 4B, the resistance value per unit length of the diamond-shaped pattern 120 becomes higher at the vicinity of the corner 120a or 120b of the diamond-shaped pattern 120 whereas becomes lower toward a center part of the diamond-shaped pattern 120. Therefore, in a case where a voltage is applied to a part of the diamond-shaped pattern 120 between the one corner 120a and the other corner 120b, the intervals of the potential distribution differ depending on the position of the part of the diamond-shaped pattern 120 between the one corner 120a and the other corner 120b. Thus, equally spaced potential distribution cannot be generated. In order to perform accurate position detection, the resistance value per unit length of the diamond pattern 120 is desired to be uniform as illustrated with a dot-dash line 4B of FIG. 4B.

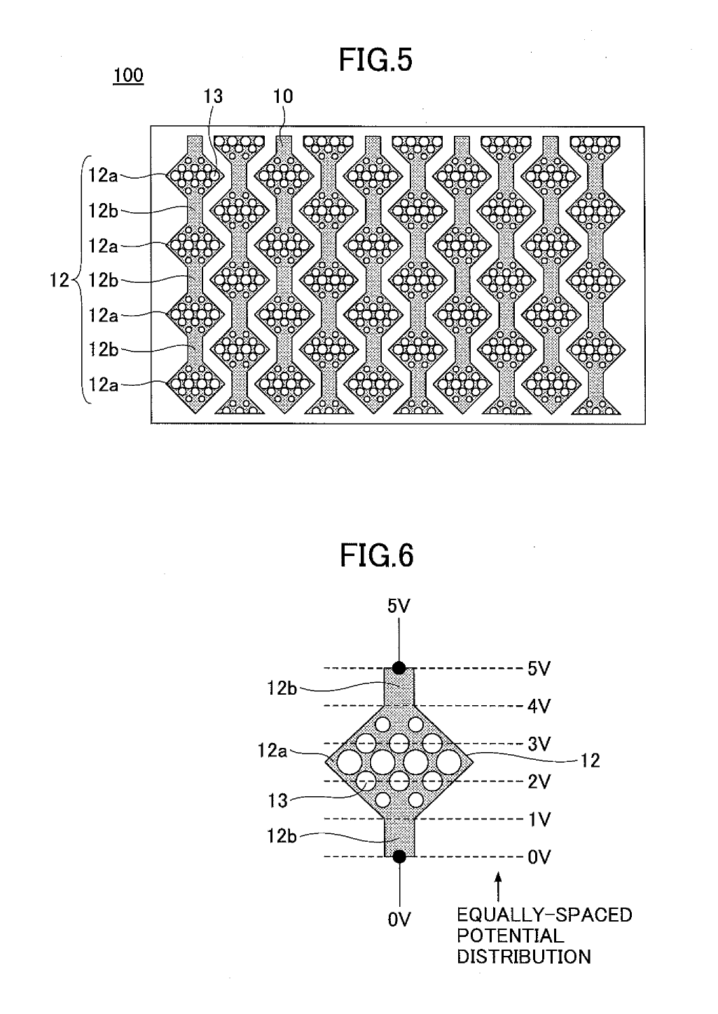

In order to generate equally spaced electrical potential distribution in the diamond-shaped parts 12a and the diamond connection parts 12b, the touch panel 100 of the first embodiment is configured to have one or more areas 13 from which a transparent conductive film is removed (hereinafter referred to as “conductive film removal areas”) provided in the diamond-shaped parts 12a as illustrated in FIGS. 5 and 6.

FIG. 5 is a schematic diagram illustrating an example of the first transparent conductive film 10 having the conductive film removal areas 13 formed in the diamond pattern 12. FIG. 6 is a schematic diagram illustrating an example of the diamond shaped part 12a illustrated in FIG. 5.

In the touch panel 100 as illustrated in FIGS. 5 and 6, equally spaced electrical potential distribution can be generated in the first transparent conductive film 10 even in a case where the first transparent conductive film 10 having the diamond pattern 12 is formed. Therefore, in this case, because the potential of the first transparent conductive film 10 and the contact position of the first transparent conductive film 10 can establish a linear relationship, accurate position detection can be performed by referring to a potential detected from a contact position of the transparent conductive film 10. The conductive film removal area 13 can be formed by removing the transparent conductive film (e.g., by etching or laser abrasion), for example, at the same time of forming the diamond pattern 12.

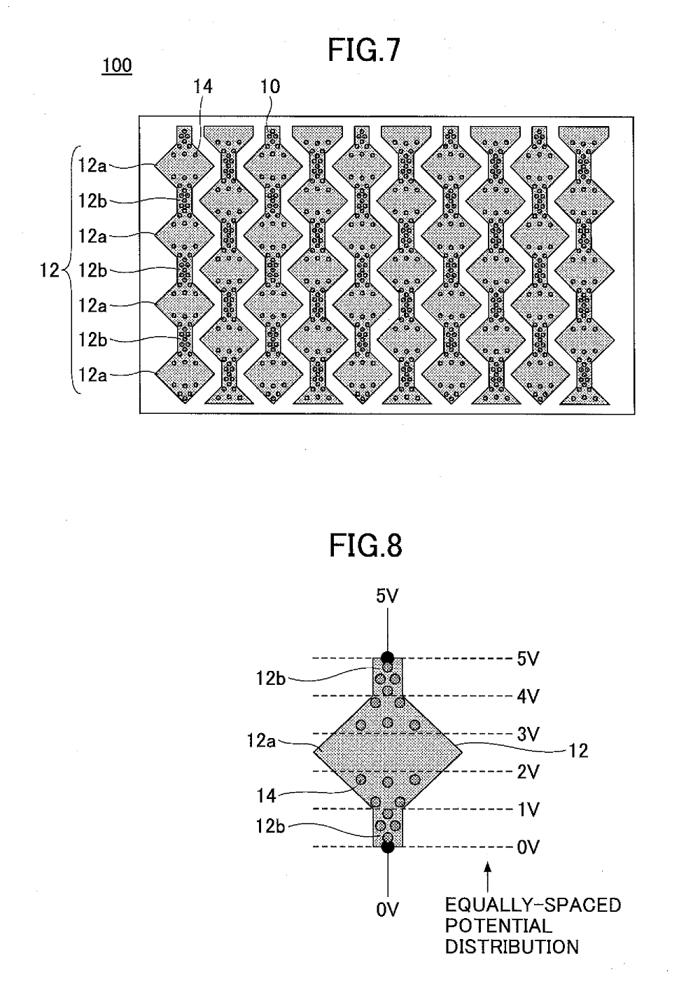

Alternatively, in order to generate equally spaced potential distribution in the diamond-shaped parts 12a and the diamond connection parts 12h, the touch panel 100 of the first embodiment may be configured to have one or more areas 14 having a conductivity higher than the conductivity of the center part of the diamond-shaped part 12a (hereinafter referred to as “high conductivity areas”) provided in the diamond connection parts 12b and/or a part of the diamond-shaped parts 12a in the vicinity of the diamond connection parts 12b as illustrated in FIGS. 7 and 8.

FIG. 7 is a schematic diagram illustrating an alternative example of the first transparent conductive film 10 having the high conductive area 14 formed in the diamond pattern 12. FIG. 8 is a schematic diagram illustrating an example of the diamond shaped parts 12a and the diamond connection parts 12b illustrated in FIG. 7.

Because the high conductive area 14 has conductivity higher than the conductivity of the center part of the diamond-shaped part 12a, equally spaced potential distribution can be generated in the first transparent conductive film 10 even in a case where the first transparent conductive film 10 having the diamond pattern 12 is formed.

Thus, with this example, accurate position detection can also be performed by referring to a potential detected from a contact position of the transparent conductive film 10 because the potential of the first transparent conductive film 10 and the contact position of the first transparent conductive film 10 can establish a linear relationship.

The high conductive area 14 can be formed with fine particles having high conductivity. For example, the high conductive area 14 may be formed by applying or printing fine particles of metal or a transparent conductive material.

### Second Embodiment

A touch panel 200 according to the second embodiment of the present invention is described. The second embodiment pertains to a wiring that is connected to the first transparent conductive film 10 having the diamond pattern 12 illustrated in FIGS. 1 and 2.

For example, in a case where a touch panel includes a first transparent conductive film having multiple rows of diamond patterns, the length of a wiring connected to one row of the diamond patterns formed in the vicinity of one end of the touch panel and the length of a wiring connected another row of the diamond patterns formed in the vicinity of the other end of the touch panel are different due to the rows of diamond patterns formed in different positions. In such case where the lengths of the wirings are different, the resistance values of the wirings are, in general, different. Therefore, the voltage drops of each wiring are different even in a case where a same amount of voltage is applied to each of the wirings. Therefore, in this case where the touch panel includes a first transparent conductive film having multiple rows of diamond patterns, the voltage applied to each row of the diamond patterns become different. As a result, the accuracy of detecting a contact position of the touch panel is degraded.

The touch panel 200 according to the second embodiment has a structure in which the resistance values of the wirings connected to multiple rows of diamond patterns 12₁-12ₙ of the first transparent conductive film 10 are substantially uniform.

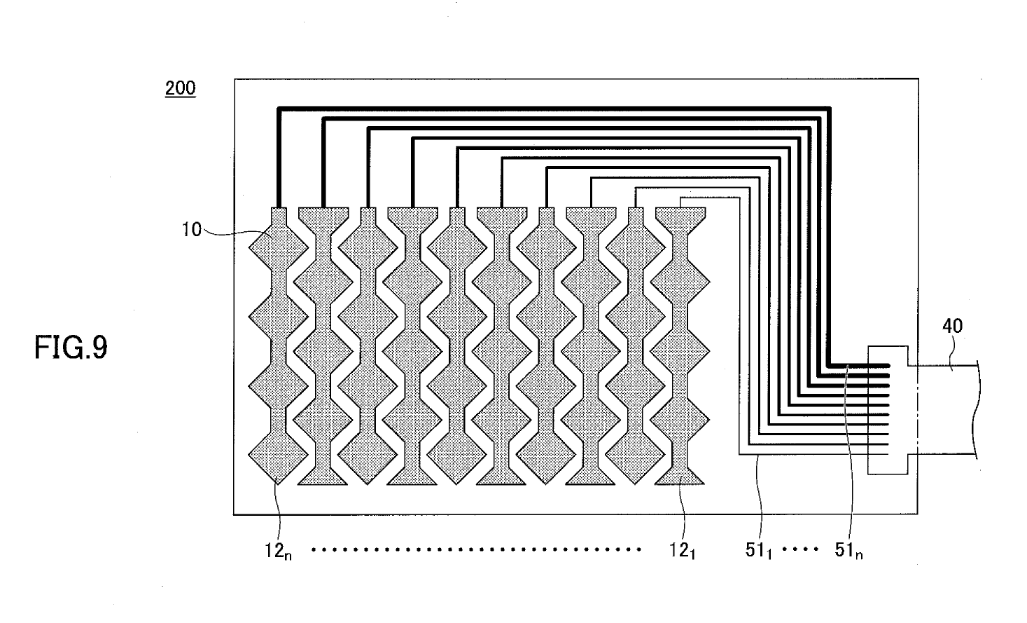

As illustrated in FIG. 9, the touch panel 200 of the second embodiment includes multiple rows of diamond patterns 12₁-12ₙ connected to corresponding wirings 51₁-51ₙ which are formed with different width. That is, the touch panel 200 of the second embodiment including the first transparent conductive film 10 has multiple diamond patterns 12₁-12ₙ connected to corresponding wirings 51₁-51ₙ of the different width.

One end of each of the wirings 51₁-51ₙ is connected to a flexible printed circuit (FPC) 40 provided in the vicinity of one end of the touch panel 200 and other end of each of the wirings 51₁-5n is connected to corresponding diamond patterns 12₁-12ₙ to connect the electrode terminals of the flexible printed circuit 40 to the corresponding diamond patterns 12₁-12ₙ and to apply voltage to the corresponding diamond pattern 12₁-12ₙ.

The multiple diamond patterns are formed from the vicinity of one end of the touch panel 200 to the vicinity of the other end of the touch panel 200. For example, a diamond pattern 12₁ is formed in the vicinity of the one end of the touch panel 200, and a diamond pattern 12ₙ is formed in the vicinity of the other end of the touch panel 200.

The wirings 51₁-51ₙ are formed in correspondence with one of the diamond patterns 12₁-12ₙ. An electrode terminal of the flexible printed circuit 40 is electrically connected to one end of the diamond pattern 12₁ by way of the wiring 51₁, and another electrode terminal of the flexible printed circuit 40 is electrically connected to one end of the diamond pattern 12, by way of the wiring 51ₙ.

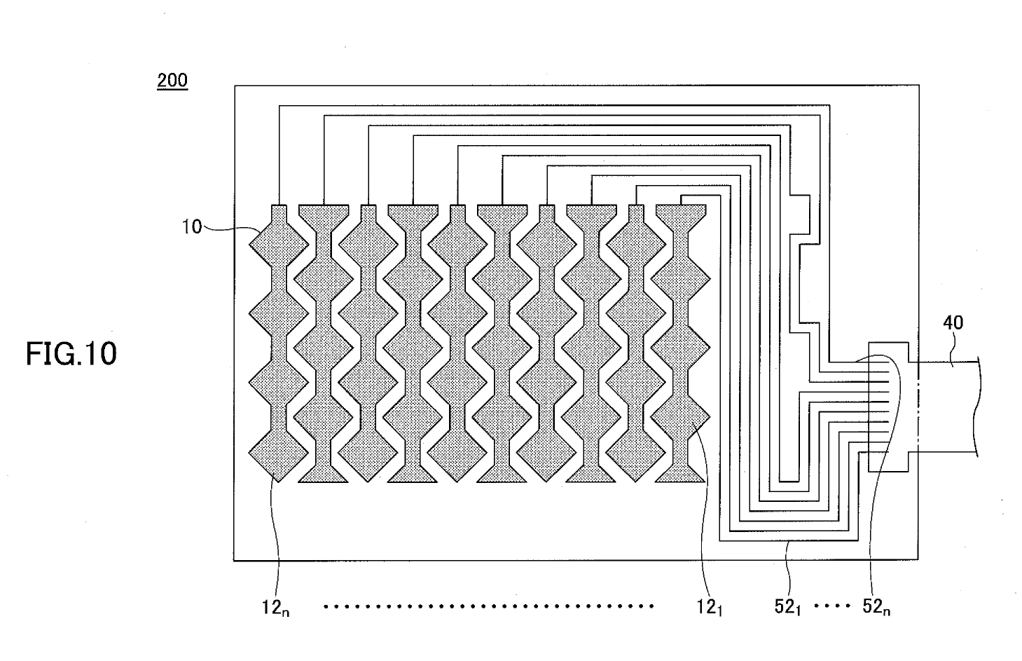

FIG. 9 and the below-described FIGS. 10, 11, 13-15 are merely schematic diagrams of illustrative examples of the touch panel according to an embodiment of the present invention. FIG. 9 illustrates the wirings 51₁-51ₙ connected to respective one ends of the diamond patterns 12₁-12ₙ and omits the wirings connected to the other ends of the diamond patterns 12₁-12ₙ. Similarly, in the below-described FIGS. 10, 11, 13-15, only the wirings connected to one ends of the diamond patterns 12₁-12ₙ are illustrated and the wirings connected to the other ends of the diamond patterns 12₁-12ₙ are omitted.

In the touch panel 200 of FIG. 9, the lengths of the wirings 51₁-51ₙ connected to the diamond patterns 12₁ₙ12ₙ become longer as the diamond patterns 12₁-12ₙ become farther from the flexible printed circuit 40. That is, the length of the wiring 51ₙ connected to the wiring pattern 12ₙ becomes longer than the length of the wiring 51₁ connected to the wiring pattern 12₁.

However, according to the touch panel 200 of the second embodiment, the resistance values of the wirings 51₁-51ₙ are substantially the same even where the lengths of the wirings 51₁-51ₙ are different, because the widths of the wirings 51₁-51ₙ positioned relatively further from the flexible printed circuit 40 is increased relative to the wiring positioned closer to the flexible printed circuit 40. Therefore, the voltages applied to the diamond patterns 12₁-12ₙ can be substantially uniform, and high accuracy position detection can be performed by the touch panel 200 having the functions of both the electrostatic capacity type touch panel and the resistant film type touch panel.

Further, according to the touch panel 200 of the second embodiment, the resistance values of the wirings 51₁-51ₙ can be made substantially same by gradually increasing the width of the wirings 51₁-51ₙ from the shortest wiring 51₁ to the longest wiring 51ₙ. The voltages applied to the diamond patterns 12₁-12₁₁ can be substantially uniform. Accordingly, the potential distribution of the diamond patterns 12₁-12ₙ of the first transparent conductive film 10 can become uniform, and position detection can be performed with high accuracy. It is to be noted that the wirings 51₁-51ₙ can be formed by, for example, screen printing a silver paste or the like.

In an alternative example, the touch panel 200 of the second embodiment may include wirings 52₁-52ₙ having substantially equal lengths and widths as illustrated in FIG. 10. In FIG. 10, the wirings 52₁-52ₙ are connected to corresponding diamond patterns 12₁-12ₙ. With this alternative example, the resistance values of the wirings 52₁-52ₙ are substantially uniform because the wirings 52₁-52ₙ are formed having substantially equal lengths and widths.

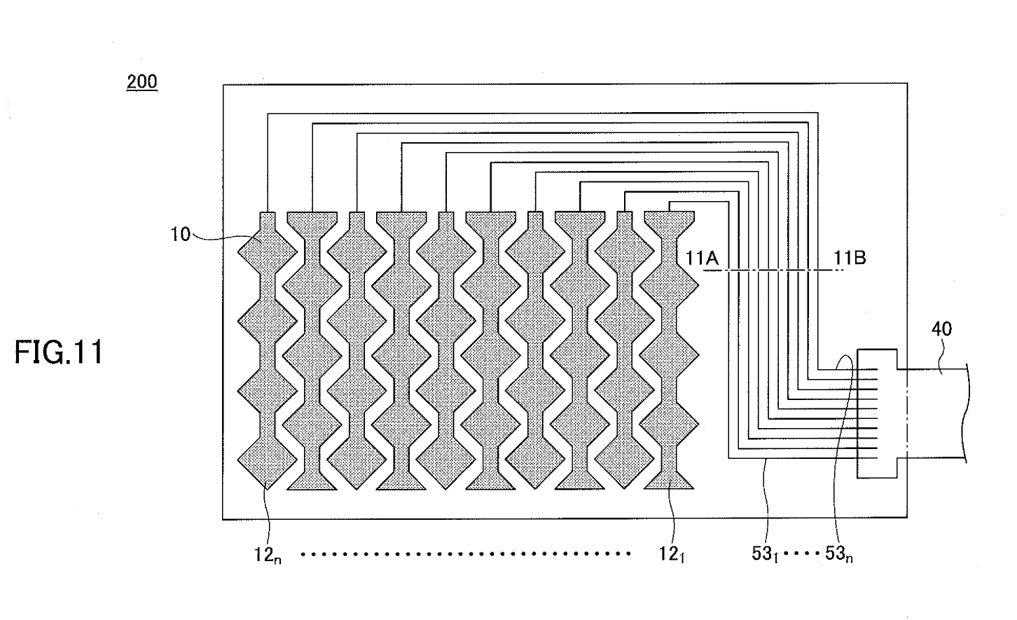

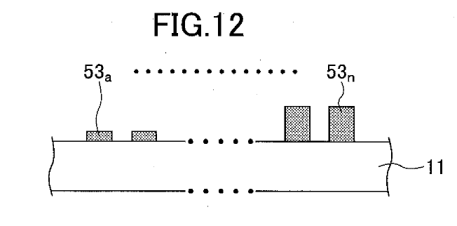

In another alternative example, the touch panel 200 of the second embodiment may include wirings 53₁-53ₙ having substantially equal widths but having a thickness greater than the thickness of others as illustrated in FIGS. 11 and 12. FIG. 12 is a cross-sectional view of the first substrate 11 taken along a dash-dot line 11A-11B of FIG. 11. In FIG. 11, the wirings 53₁-53ₙ are connected to corresponding diamond patterns 12₁-12ₙ. In order for the resistance values of the wirings 53₁-53ₙ to become substantially uniform, a portion of the wirings 53₁-53ₙ is formed having a thickness different from the other wiring. As illustrated in FIG. 12, wiring 53ₙ which is connected to the diamond pattern 12ₙ positioned far from the flexible printed circuit 40 has a thickness greater than the thickness of the other wirings 53ₐ connected to the diamond pattern positioned closer to the flexible printed circuit. According to the embodiment illustrated in FIGS. 11 and 12, resistance values of the wirings 53₁-53ₙ can be substantially uniform.

As described above, the touch panels 200 illustrated in FIGS. 9-12 allow the resistance values of the wirings corresponding to the diamond patterns 12₁-12ₙ to become substantially uniform. The configurations illustrated in FIGS. 9-12 can be generalized as follows.

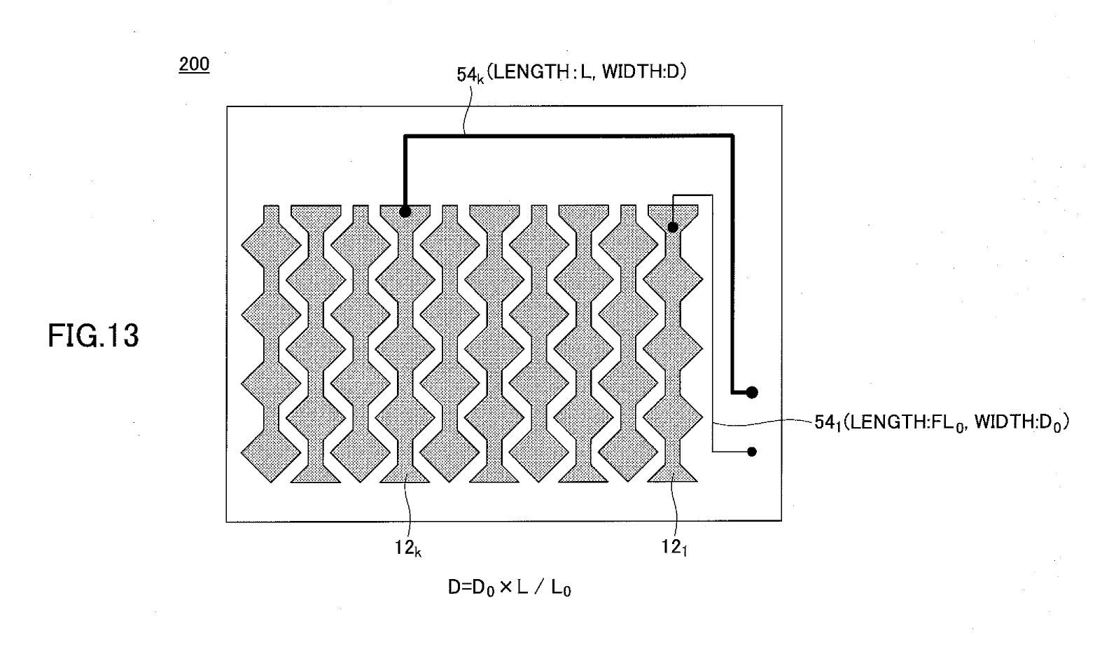

As illustrated in FIG. 13, in a case where a wiring 54₁ connected to the wiring pattern 12₁ has a width of D₀ and a length of L₀, and a wiring 54k connected to a diamond pattern 12ₖ has a width of D and a length of L, the touch panel 200 is formed to satisfy a relationship of “D≈D₀×L/L₀”. It is preferable to form the touch panel 200 to satisfy a relationship of “D=D₀×L/L₀”. Accordingly, highly accurate position detection can be performed by the touch panel 200 having the functions of both the electrostatic capacity type touch panel and the resistant film type touch panel. It is to be noted that “k” is a natural number satisfying a relationship of “1<k<n”.

In another alternative example, the touch panel 200 of the second embodiment may include diamond patterns 12₁-12ₙ in which the contact points 56₁-56ₙ connected to corresponding wirings 55₁⁻55ₙ are provided at different positions of the diamond patterns 12₁-12ₙ. That is, because the transparent conductive films constituting the diamond patterns 12₁-12ₙ have a relatively high resistance, the potential distributions of the diamond patterns 12a-12n can be made substantially uniform by changing the positions of the contact points 56₁-56ₙ.

By arranging the contact point 56ₙ connected to the wiring 55ₙ at a position more inward (further away from the one end of the diamond pattern) compared to the contact point 56₁ connected to the wiring 55₁, the potential distributions in the diamond pattern 12₁ and the diamond pattern 12ₙ can be substantially uniform. Accordingly, by forming the touch panel 200 so that the positions of the contact points 56₁-56ₙ connected to the wirings 55₁-55ₙ are arranged more inward of the diamond patterns 12₁-12ₙ in this order, the potential distributions of the diamond patterns 12₁-12ₙ can be substantially uniform.

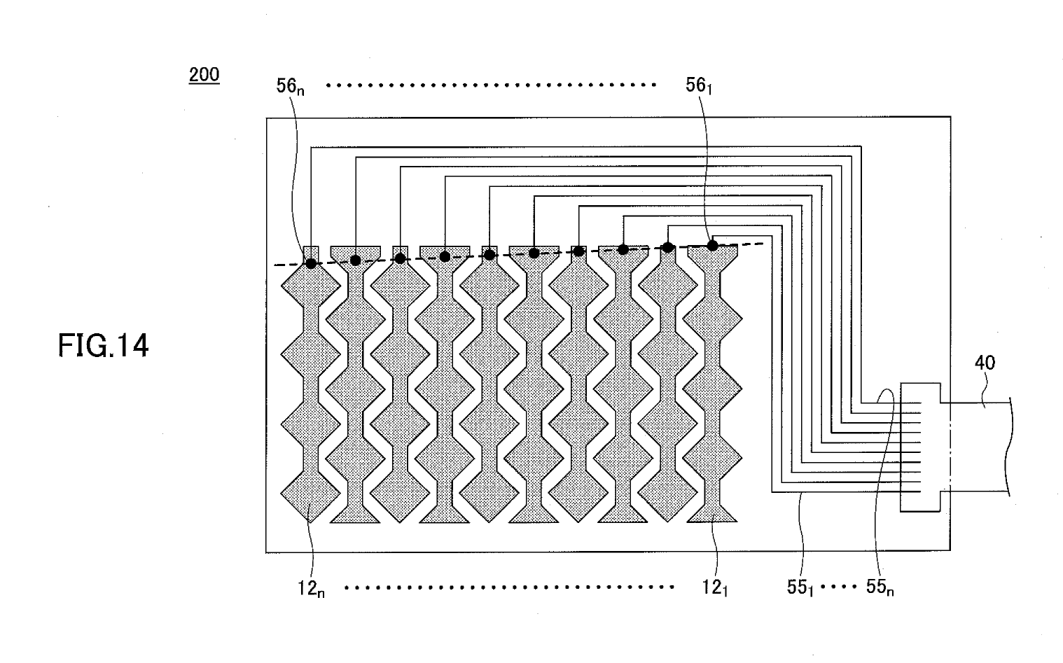

Next, a case of generalizing the touch panel 200 having the configuration illustrated in FIG. 14 is described. The touch panel illustrated in FIG. 14 is formed so that the values of the resistance of wirings 55₁-55ₖ become substantially constant with respect to the sum of the resistance of each wiring 55₁-55ₖ connected to the contact points 56₁-56ₖ and the resistances of the corresponding diamond patterns 14₁-14ₖ.

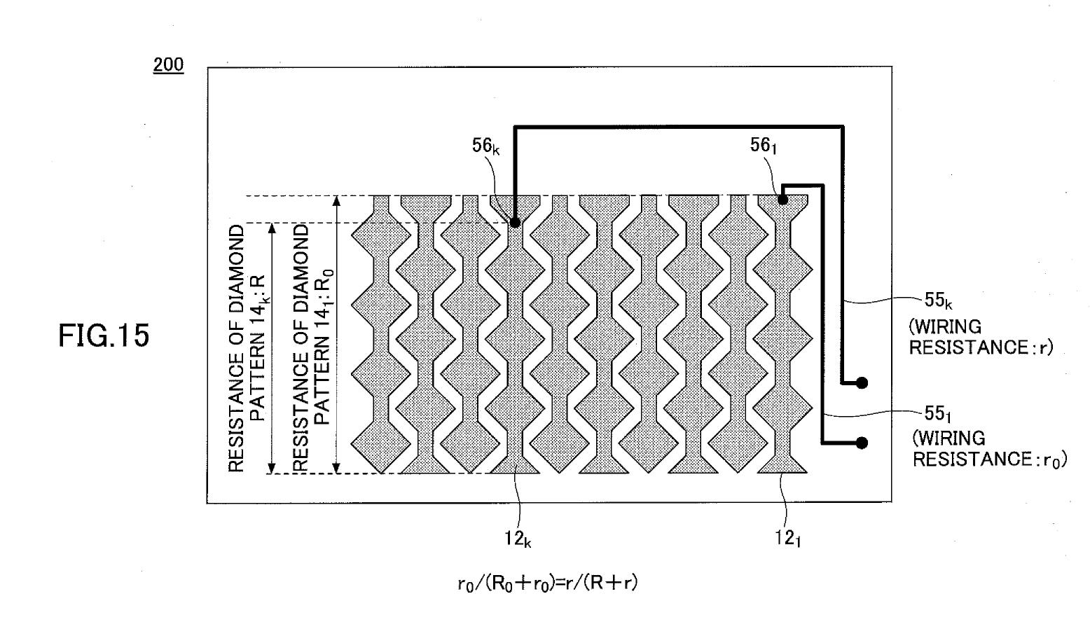

That is, as illustrated in FIG. 15, the touch panel 200 is formed to satisfy a relationship of “r₀/(R₀+r₀)≈r/(R+r)” in a case where a resistance of the wiring 55₁ connected to the contact point 56₁ on one end of the diamond pattern 12₁ is “r₀”, a resistance of a part of the diamond pattern 12₁ between the contact point 56₁ and the other end of the diamond pattern 12₁ is “R₀”, a resistance of the wiring 55ₖ connected to the contact point 56ₖ on one end of the diamond pattern 12ₖ is “r”, and a resistance of a part of the diamond pattern 12ₖ between the contact point 56ₖ and the other end of the diamond pattern 12ₖ is “R”. It is more preferable to form the touch panel 200 to satisfy a relationship of “r₀/(R₀+r₀)=r/(R+r)”.

According to the embodiment illustrated in FIG. 15, high accuracy position detection can be performed by the touch panel 200 having the functions of both the electrostatic capacity type touch panel and the resistant film type touch panel. Other than the details described above in the second embodiment, the configuration of the touch panel 200 of the second embodiment is substantially the same as the configuration of the touch panel 100 of the first embodiment.

### Third Embodiment

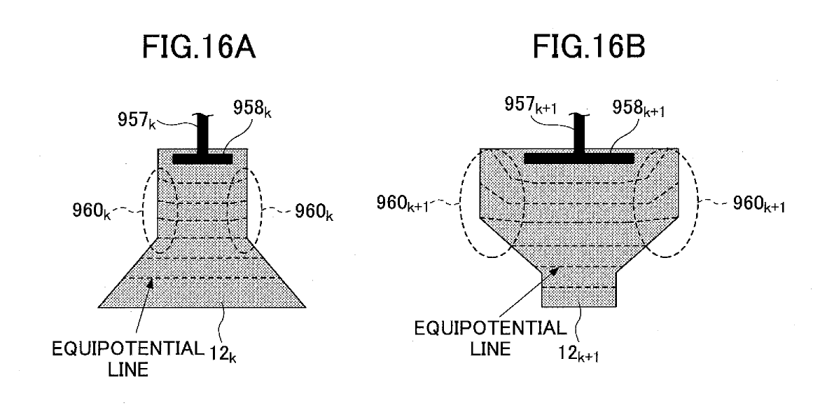

Next, a touch panel 300 according to the third embodiment of the present invention is described. The third embodiment pertains to a shape of a contact part between a single row of a diamond pattern 12 of the first transparent conductive film 10 and a wiring 57. According to a comparative example illustrated in FIGS. 16A and 16B, in a case where a contact part 958ₖ having substantially straight linear shape and contacting an end part of the diamond pattern 12ₖ is formed in a wiring 957ₖ contacting the end part of the diamond pattern 12ₖ of the first transparent conductive film 10, an area having a distorted potential 960ₖ (hereinafter also referred to as “distorted potential area”) is generated at the end part of the diamond pattern 12ₖ in the vicinity of the contact part 958ₖ. Similarly, in the case where a contact part 958ₖ₊₁ having substantially straight linear shape and contacting an end part of the diamond pattern 12ₖ₊₁ is formed in a wiring 957ₖ₊₁ contacting the end part of the diamond pattern 12ₖ₊₁, another distorted potential area 960ₖ₊₁ is generated at the end part of the diamond pattern 12ₖ₊₁ in the vicinity of the contact part 958ₖ. In this case, the accuracy of position detection is degraded due to the distorted potentials in the distorted potential areas 960ₖ and 960ₖ₊₁.

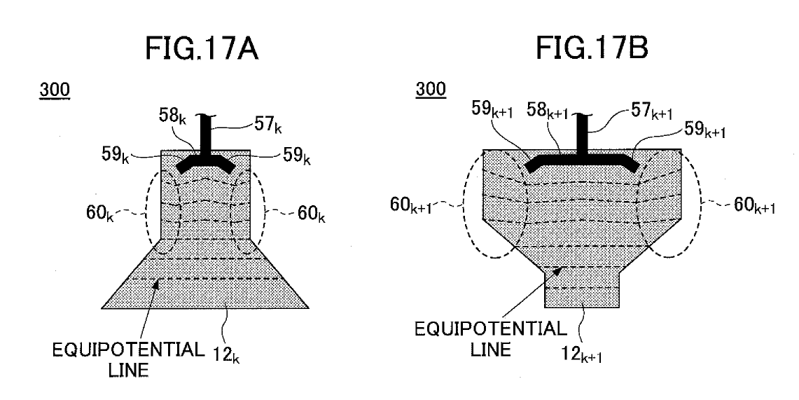

According to the touch panel 300 of the third embodiment, in addition to a contact part 58ₖ contacting an end part of the diamond pattern 12ₖ, an end part 59ₖ bent toward the diamond pattern 12ₖ is formed on both sides of the contact part 58ₖ. Likewise, in FIG. 17B, in addition to a contact part 58ₖ₊₁ contacting an end part of the diamond pattern an end part 59ₖ₊₁ bent toward the diamond pattern 12ₖ₊₁ is formed on both sides of the contact part 58ₖ₊₁.

By forming the contact part 58ₖ including the end part 59ₖ and the contact part 58ₖ₊₁ including the end part 59ₖ₊₁ the distortion of the potential distribution can be reduced in an area 60ₖ of the diamond pattern 12ₖ and an area 60ₖ₊₁ of the diamond pattern 12ₖ₊₁ comparing to the contact part illustrated in FIGS. 16A and 16B. Thereby, the accuracy of detecting the contact position can be improved.

Other than the details described above in the second embodiment, the configuration of the touch panel 300 of the third embodiment is substantially the same as the configuration of the touch panel 200 of the second embodiment.

With the above-described embodiments of the present invention, a thin touch panel including the features of both an electrostatic capacity type touch panel and a resistant film type touch panel and having high accurate position detection accuracy can be provided.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A touch panel comprising:
a first conductive film including conductive patterns each extending in one direction; and
a second conductive film facing the first conductive film;
wherein each of the conductive patterns includes a plurality of diamond-shaped parts aligned in the one direction, and a connection part connecting adjacent diamond-shaped parts each other, and
each conductive pattern has a uniform resistance value per unit length.

2. The touch panel as claimed in claim 1,
wherein each diamond-shaped part has an area from which a transparent conductive film is partially removed.

3. The touch panel as claimed in claim 1,
wherein each conductive pattern has an area formed in the connection part or in a portion of the each diamond-shaped part in a vicinity of the connection part, that has a conductivity higher than a conductivity of a center part of the diamond-shaped part.

4. A touch panel comprising:
a first conductive film including conductive patterns each extending in one direction, the conductive pattern includes a plurality of diamond-shaped parts aligned in the one direction, and a connection part connecting adjacent diamond-shaped parts each other;
a second conductive film facing the first conductive film; and
a plurality of wirings each corresponds and connected to one of the conductive patterns for connecting the corresponding conductive pattern to an external circuit;
wherein a sum of a resistance value of the wiring and a resistance value of the corresponding conductive pattern of each combination of the wiring and the corresponding conductive pattern is substantially same.

5. The touch panel as claimed in claim 4, wherein each wiring has substantially same resistance value.

6. The touch panel as claimed in claim 5, wherein each wiring have substantially the same length.

7. The touch panel as claimed in claim 5, wherein the wiring which length is relatively greater than a length of the other wiring has a width relatively greater than a width of the other wiring.

8. The touch panel as claimed in claim 5, wherein the wiring which length is relatively greater than a length of the other wiring has a thickness relatively greater than a thickness of at least a portion of the other wiring.

9. The touch panel as claimed in claim 4, wherein a position to which each of the plural wirings is connected differs according to the corresponding conductive pattern.

10. A touch panel comprising:
a first conductive film including conductive patterns each extending in one direction, the conductive pattern includes a plurality of diamond-shaped parts aligned in the one direction, and a connection part connecting adjacent diamond-shaped parts each other;
a second conductive film facing the first conductive film; and
a plurality of wirings each corresponds and connected to one of the conductive patterns for connecting the corresponding conductive pattern to an external circuit;
wherein each wiring includes a contact part at its end that contacts with the corresponding conductive pattern, and an end part formed at a side of thee contact part that is bent toward the diamond-shaped part.
